(19) United States
(12) Patent Application Publication
(10) Pub. No.: US 2006/0267659 A1
(43) Pub. Date: Nov. 30, 2006

(54) HIGH-SPEED, LOW-NOISE VOLTAGE-CONTROLLED DELAY CELL

(76) Inventors: Jiu-Liang Tsai, Pingtung City (TW); Yuh-Kuang Tseng, Taoyuan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/908,782

(22) Filed: May 26, 2005

(51) Int. Cl. H03H 11/26

(52) U.S. Cl. 327/280

(57) ABSTRACT

A high-speed low-noise voltage-controlled delay cell is disclosed. The source of a first and a second transistor are coupled to a first voltage wire. The drains of first and third transistor coupling the gates of second and fourth transistor output a second output signal. The drains of second and fourth transistor coupling the gates of firth and third transistor output a first output signal. The sources of second and fourth transistor are coupled to a second voltage wire. The output ends of first and third converter are coupled to the drain of the first transistor. The output ends of second and fourth converter are coupled to the drain of the second transistor. The input ends of first and second converter receive a first and a second input signal, respectively. The input ends of third and fourth converter receive a control voltage.

### BACKGROUND OF THE INVENTION

1. Field of the Invention

The present invention relates to a voltage-controlled delay cell. In particular, it relates to a high-speed, low-noise voltage-controlled delay cell.

2. Description of the Related Art

For controlling the timing (or phase) of control signals during transmission, a voltage-controlled delay cell is often used to adjust the phase of a control signal. The voltage-controlled delay cell delays a received input signal for a delay time, then outputs an output signal. Wherein, the voltage-controlled delay cell also receives a control voltage to adjust the delay time. In the following, a voltage-controlled oscillator (VCO) is taken as an example to explain the application of a voltage-controlled delay cell.

The development of VCO have taken a long way, and it still plays a key role in current technology due to its broad applications and high developing potential. Many advantages of VCOs, such as increasing operation frequency, low power consumption and low-noise output, are expected to be continuously improved and enhanced.

A VCO employs voltage-controlled delay cells connected in series, utilizes a control voltage as a reference and, by means of the feedback of closed-loop control system, and produces an oscillation with a frequency corresponding to a control voltage. That is the principle of voltage-controlled oscillation.

To improve the performance of the VCO, the manufacturers put much effort into its designs. FIG. 1 is a schematic circuit layout of a conventional voltage-controlled oscillator. Referring to FIG. 1, an inverter 100 and a pull-down transistor 102 below the inverter form a voltage-controlled delay cell. Three voltage-controlled delay cells are connected in 3-stages series to form a VCO to output a clocking signal Vout. The gate of the pull-down transistor 102 receives a control voltage Vcon based on which the transition time/delay time of the inverter 100 and, consequently, the oscillation frequency are controlled.

FIG. 2 is a schematic circuit layout of another conventional VCO. The VCO is formed by voltage-controlled delay cells 200 connected in 3-stages series, and each of the voltage-controlled delay cells has a differential input and a differential output. Wherein, the voltage-controlled delay cell with the differential input/output modes can be formed by a differential amplifier pair. In FIG. 2, the voltage Vcon controls the delay time of each stage of voltage-controlled delay cells 200. Consequently, the oscillation frequency of an output signal Vo is controlled.

In the conventional technology, many designs of the voltage-controlled delay cells are made for VCOs. For example, the U.S. Pat. No. 6,304,149 introduces a differential delay stage circuit as shown in FIG. 3. The circuit comprises input stage transistors 300 and 302, gain control transistors 304 and 306, and active load transistors 308 and 310. The weakness of such layout is that the adjustable range of the oscillation frequency is too small when the delay cells are connected in series as a ring-shaped VCO.

FIG. 4 is a schematic layout of another conventional differential delay circuit. The circuit includes input stage transistors 400 and 402, positive feedback transistors 404 and 406, and active load transistors for controlling gain 408 and 410. In FIG. 4, the differential delay circuit delays the received differential input signals Vi+ and Vi− for a delay time, then outputs differential output signals Vo+ and Vo−. Wherein, the voltage-controlled delay cells further receive the control voltage Vcon based on which the delay time is adjusted. In comparison with FIG. 3, FIG. 4 uses the control voltage Vcon to control active load transistors for controlling gain 408 and 410, thus, the adjustable range of the delay time is larger. If differential delay circuits in FIG. 4 are connected in series as a VCO (similar to the configuration in FIG. 2), the adjustable range of the oscillation frequency is larger than the one in FIG. 3. Referring to FIG. 5, it is a graphic chart showing the relationship of the frequency vs. the control voltage of a ring-shaped VCO formed by connecting the delay cells in series with the layout of FIG. 4. Although such circuit layout has a broad adjustable frequency range, such layout is not easy to be controlled since the oscillation frequency adjustment is too sensitive to the control voltage.

### SUMMARY OF THE INVENTION

The object of the present invention is to provide a high-speed low-noise voltage-controlled delay cell used for receiving a control voltage based on which a delay time is adjusted. With the high-speed, low-gain, and low-noise performance, the delay cell is suitable for forming a voltage-controlled oscillator (VCO) in a phase locked loop (PLL) with a sufficient adjustable oscillation frequency range and lower sensitivity of control voltage to frequency adjustment.

The present invention provided a high-speed low-noise voltage-controlled delay cell used for receiving a first input signal and a second input signal and delaying both signals for a delay time, then outputting a first output signal and a second output signal. The delay cell also receives a control voltage based on which the delay time is adjusted. The high-speed low-noise voltage-controlled delay cell comprises a first transistor, a second transistor, a third transistor, a fourth transistor, a first converter and a second converter. The source of the first transistor is coupled to a first voltage wire and the drain signal of the first transistor is the second output signal. The gate of the second transistor is coupled to the drain of the first transistor, the drain of the second transistor is coupled to the gate of the first transistor, and the source of the second transistor is coupled to the first voltage wire. Wherein, the drain signal of the second transistor is the first output signal. The gate of the third transistor is coupled to the drain of the second transistor, the drain of the third transistor is coupled to the drain of the first transistor, and the source of the third transistor is coupled to a second voltage wire. The gate of the fourth transistor is coupled to the drain of the first transistor, the drain of the fourth transistor is coupled to the gate of the third transistor, and the source of the fourth transistor is coupled to the second voltage wire. The input end of the first converter receives the first input signal, while the output end of the first converter is coupled to the drain of the first transistor. The input end of the second converter receives the second input signal, while the output end of the second converter is coupled to the drain of the second transistor. The input end of the third converter receives the control voltage, while the output end of the third converter is coupled to the drain of the first transistor. The input end of a fourth converter receives the control voltage, while the output end of the fourth converter is coupled to the drain of the second transistor.

By means of the above-described structure in the present invention and a specific length-width ratio, the provided delay cell is capable of operating at a high-speed and decreasing the gain. When connecting the provided delay cells in series as a ring-shaped VCO, the adjustable frequency thereof is higher and the sensitivity of a control voltage to the frequency adjustment is decreased.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve for explaining the principles of the invention.

FIG. 1 is a schematic circuit drawing of a conventional voltage-controlled oscillator.

FIG. 2 is a schematic circuit drawing of a conventional voltage-controlled oscillator, formed by connecting amplifiers in 3-stages series.

FIG. 3 is a schematic circuit drawing of a conventional voltage-controlled delay cell.

FIG. 4 is a schematic circuit drawing of another conventional voltage-controlled delay cell.

FIG. 5 is a graphic chart showing the relationship of the frequency vs. the control voltage of a voltage-controlled oscillator formed by connecting the voltage-controlled delay cells in series in FIG. 4.

FIG. 6 is a schematic circuit drawing of a high-speed low-noise voltage-controlled delay cell in an embodiment of the present invention.

FIG. 7 is a graphic chart showing the relationships of the frequency vs. the control voltage of the voltage-control oscillators formed by the voltage-controlled delay cells in FIG. 4 and FIG. 6, respectively.

FIG. 8 is a schematic circuit drawing of a high-speed low-noise voltage-controlled delay cell in another embodiment of the present invention.

FIG. 9 is a schematic circuit drawing of a voltage-controlled delay cell in an embodiment of the present invention.

FIG. 10 is a schematic circuit drawing of a voltage-controlled delay cell in another embodiment of the present invention.

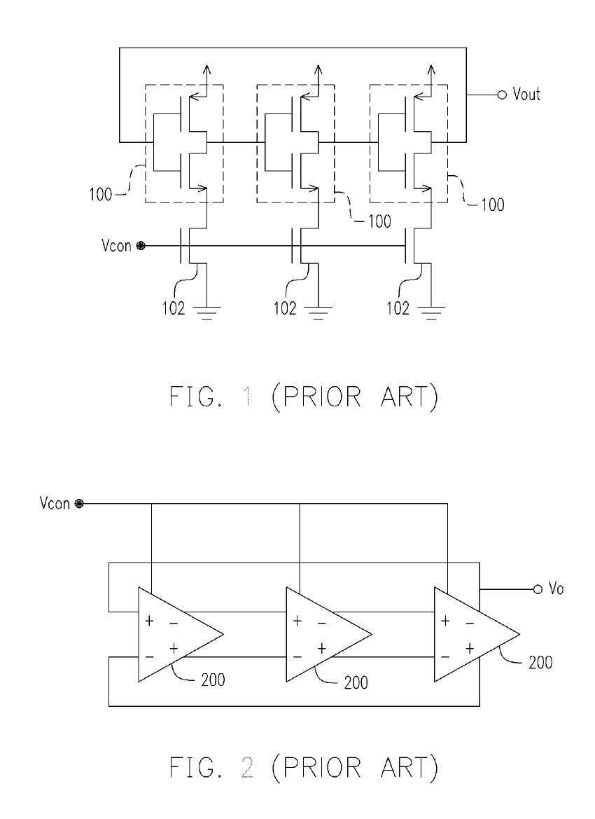

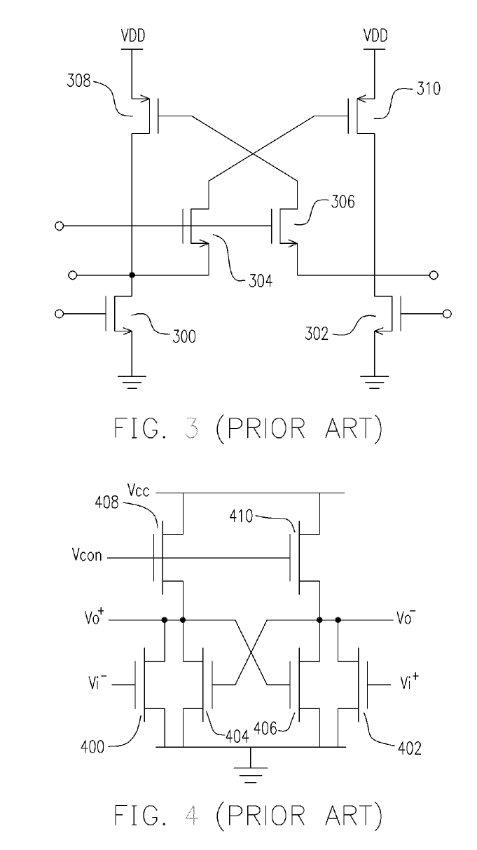

### DESCRIPTION OF THE EMBODIMENTS

FIG. 6 is a schematic circuit drawing of a high-speed low-noise voltage-controlled delay cell in an embodiment of the present invention. The delay cell has a positive input end Vi+, a negative input end Vi−, a positive output end Vo+, a negative output end Vo− and a control voltage end Vcon. The delay cell mainly comprises a first converter 600, a second converter 602, a third converter 604, a fourth converter 606, a first transistor 608, a second transistor 610, a third transistor 612 and a fourth transistor 614. The high-speed low-noise voltage-controlled delay cell receives a first input signal via the positive input end Vi+ and a second input signal via the negative input end Vi−, respectively. Then, after a delay time, a first output signal and a second output signal are output from the positive output end Vo+ and the negative output end Vo−, respectively. Wherein, the control voltage end Vcon receives a control voltage to adjust the delay time.

In FIG. 6, the source of the first transistor 608 is coupled to a first voltage wire GND (in the embodiment, the first voltage wire is, for example, a grounding wire). The drain of the first transistor 608 is coupled to the negative output end Vo−, and the gate of the first transistor 608 is coupled to the positive output end Vo+. The source of the second transistor 610 is coupled to the first voltage wire GND, the drain of the second transistor 610 is coupled to the positive output end Vo+, and the gate of the second transistor 610 is coupled to the negative output end Vo−. The source of the third transistor 612 is coupled to the second voltage wire Vcc (in the embodiment, the second voltage wire is, for example, a power supply voltage wire), the drain of the third transistor 612 is coupled to the negative output end Vo−, and the gate of the third transistor 612 is coupled to the positive output end Vo+. The source of the fourth transistor 61 4 is coupled to the second voltage wire Vcc, the drain of the fourth transistor 614 is coupled to the positive output end Vo+, and the gate of the fourth transistor 614 is coupled to the negative output end Vo−.

The input end of the first converter 600 is coupled to the positive input end Vi+ of the voltage-controlled delay cell to receive and convert the first input signal. The output end of the first converter 600 is coupled to the negative output end Vo− and the drain of the first transistor. The input end of the second converter 602 is coupled to the negative input end Vi− of the voltage-controlled delay cell to receive and convert the second input signal, while the output end of the second converter 602 is coupled to the positive output end Vo+ and the drain of the second transistor. The input end of the third converter 604 is coupled to the control voltage end Vcon to receive the control voltage, and the output end thereof is coupled to the negative output end Vo− and the drain of the first transistor. The input end of the fourth converter 606 is coupled to the control voltage end Vcon to receive the control voltage, and the output end thereof is coupled to the positive output end Vo+ and the drain of the second transistor.

In the embodiment, both the above-mentioned first transistor 608 and the second transistor 610 are, for example, N-type MOSFETs (metal oxide semiconductor field effect transistors), and the third transistor 612 and the fourth transistor 614 are, for example, P-type MOSFETs.

In the embodiment, the above-mentioned first converter 600 is implemented by, for example, a fifth transistor 616. The gate of the fifth transistor 616 receives the first input signal, the source thereof is coupled to the first voltage wire GND, and the drain of thereof is coupled to the negative output end Vo− and the drain of the first transistor. By this way, the first input signal is inversely amplified with an opposite polarity and sent to the negative output end Vo−. The above-mentioned second converter 602 is implemented by, for example, a sixth transistor 618. The gate of the sixth transistor 618 receives the second input signal, the source thereof is coupled to the first voltage wire GND, the drain of thereof is coupled to the positive output end Vo+ and the drain of the first transistor. By this way, the second input signal is inversely amplified with an opposite polarity and sent to the positive output end Vo+. The first transistor 608 and the second transistor 610 are also used for producing a positive feedback to increase the overall gain. The third transistor 612 and the fourth transistor 614 enable the voltage-controlled delay cell of the present invention to properly operate even the control voltage is close to the voltage of the second voltage wire, thus a broader control voltage input range is achieved.

In the above-described embodiment, the third converter 604 and the fourth converter 606 mainly serve for controlling the gain so that the delay time of the cell is controlled. The third converter 604 and the fourth converter 606 can be implemented by a seventh transistor 620 and an eighth transistor 622, respectively. The source of the seventh transistor 620 is coupled to the second voltage wire Vcc, the gate of the seventh transistor 620 is coupled to the control voltage end Vcon to receive the control voltage, and the drain of the seventh transistor 620 is coupled to the negative output end Vo−. The source of the eighth transistor 622 is coupled to the second voltage wire Vcc, the gate of the eighth transistor 622 is coupled to the control voltage end Vcon to receive the control voltage, and the drain of the eighth transistor 622 is coupled to the positive output end Vo+. In this configuration, the operation mode is by inputting the control voltage at the control voltage end Vcon and taking both the seventh transistor 620 and the eighth transistor 622 as variable resistors, as the voltage at the control voltage end Vcon increases, accordingly raising the start-up resistance of the seventh transistor 620 and the eighth transistor 622. As a result, the delay time of outputs is longer.

In the embodiment, both the fifth transistor and the sixth transistor are N-type MOSFETs, while both the seventh transistor and the eighth transistor are P-type MOSFETs.

In the embodiment, the channel length-width ratio of each transistor must meet the following conditions. The length-width ratio of the fifth transistor 616 is equal to that of the sixth transistor 618, the length-width ratio of the first transistor 608 is equal to that of the second transistor 610, and the length-width ratio of the third transistor 612 is equal to that of the fourth transistor 614. Wherein, the length-width ratio of the fifth transistor 616 must be larger than or equal to that of the first transistor 608, and the length-width ratio of the first transistor 608 must be larger than or equal to that of the third transistor 612.

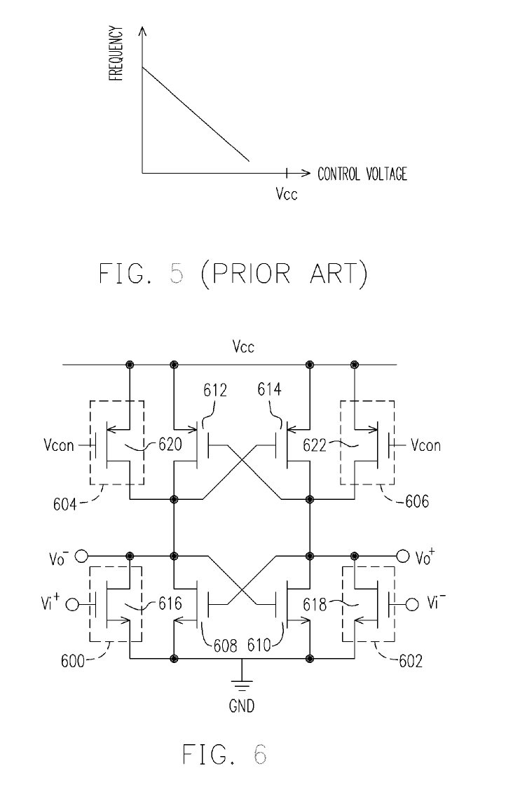

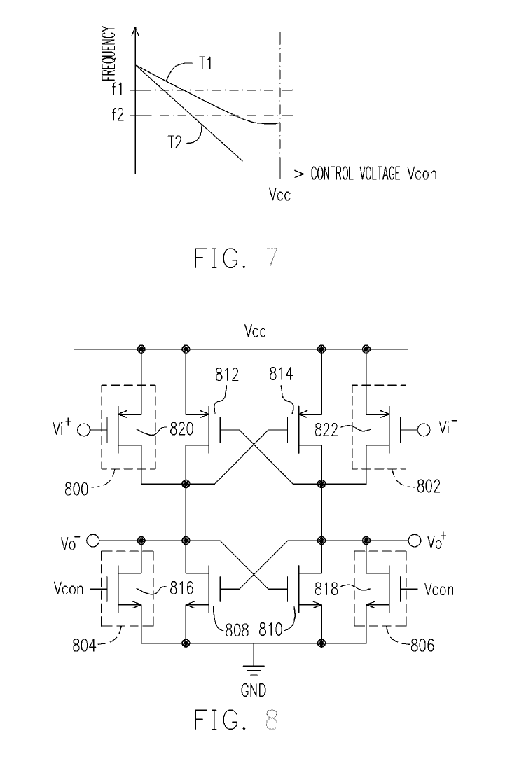

To better explain the embodiment of the present invention, the voltage-controlled delay cell in FIG. 6 is used to form a ring VCO for a simulation. The configuration of the ring VCO can be referred to FIG. 2. Namely, suppose the positive input end (+), the negative input end (−), the positive output end (+) and the negative output end (−) of the delay cell 200 in FIG. 2 are the positive input end Vi+, the negative input end Vi−, the positive output end Vo+ and the negative output end Vo− in FIG. 6, respectively. The simulation is as the curve T shown in FIG. 7. For comparison, the simulation result in FIG. 5 (namely, the simulation result by connecting the differential delay circuits in FIG. 4 in series to form a ring VCO), the curve T2, is also shown in FIG. 7. It can be seen from FIG. 7, in the operation frequency range, f1 (for example, 500 MHz) to f2 (for example, 200 MHz), the adjustable range of the control voltage Vcon from the curve T1 is close to the difference between the power supply voltage and the grounding voltage in the embodiment of the present invention. The overall adjustable frequency range gets smaller, but the sensitivity of the control voltage to the frequency adjustment is decreased which leads to a more precise control.

For those skilled in the art, it is apparent that the present invention is not limited to the above-described embodiment. FIG. 8, for example, is another embodiment of the present invention. Referring to FIG. 8, a first converter 800 and a second converter 802 can be implemented by a ninth transistor 820 and a tenth transistor 822, respectively. The gate of the ninth transistor 820 receives a first input signal, the source thereof is coupled to a second voltage wire Vcc, and the drain thereof is coupled to a negative output end Vo− and the drain of a first transistor 808. By this way, the first input signal is inversely amplified with an opposite polarity and sent to the negative output end Vo−. The gate of the tenth transistor 822 receives a second input signal, the source thereof is coupled to the second voltage wire Vcc, and the drain thereof is coupled to a positive output end Vo+ and the drain of a second transistor 810. By this way, the second input signal is inversely amplified with an opposite polarity and sent to the positive output end Vo+.

A third converter 804 and a fourth converter 806 in FIG. 8 can be implemented by an eleventh transistor 816 and a twelfth transistor 818, respectively. The source of the eleventh transistor 816 is coupled to a first voltage wire GND, the gate of the eleventh transistor 816 is coupled to a control voltage end Vcon to receive a control voltage, and the drain of the eleventh transistor 816 is coupled to the negative output end Vo−. The source of the twelfth transistor 818 is coupled to the first voltage wire GND, the gate of the twelfth transistor 818 is coupled to the control voltage end Vcon to receive the control voltage, and the drain of the twelfth transistor 818 is coupled to the positive output end Vo+. The transistors 808˜814 in FIG. 8 are similar to the transistors 608˜614 in FIG. 6, so are not repeated.

In the embodiment shown in FIG. 8, the ninth transistor 820 and the tenth transistor 822 in the first converter 800 and the second converter 802 are P-type MOSFETs, while the eleventh transistor 816 and the twelfth transistor 818 in the third converter 804 and the fourth converter 806 are N-type MOSFETs.

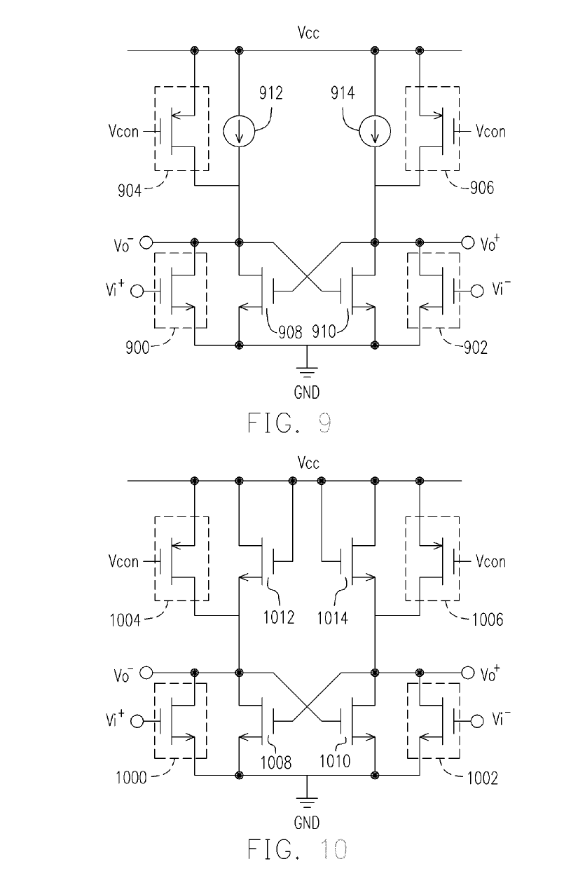

FIG. 9 is a schematic circuit drawing of a voltage-controlled delay cell in another embodiment of the present invention. The difference between FIG. 9 and FIG. 6 is the third transistor 612 and the fourth transistor 614 in FIG. 6 are replaced by a first current source 912 and a second current source 914 in FIG. 9. The others in FIG. 9 are the same as in FIG. 6.

FIG. 10 is a schematic circuit drawing of a voltage-controlled delay cell in another embodiment of the present invention. In comparison with FIG. 6, the difference between FIG. 10 and FIG. 6 is the connection method of the third transistor and the fourth transistor. Both the third transistor 1012 and the fourth transistor 1014 in FIG. 10 are diode-connected to the second voltage wire Vcc. The others in FIG. 10 are the same as in FIG. 6.

It will be apparent to those skilled in the art that various modifications and variations can be made to the structure of the present invention without departing from the scope or spirit of the invention. In view of the foregoing, it is intended that the specification and examples to be considered as exemplary only, with a true scope and spirit of the invention being indicated by the following claims and their equivalents.

What is claimed is:

1. A high-speed low-noise voltage-controlled delay cell used for delaying a received first input signal and a received second input signal for a delay time and then outputting a first output signal and a second output signal, further receiving a control voltage to adjust said delay time, the high-speed low-noise voltage-controlled delay cell comprising:
a first transistor having a source, a gate and a drain, wherein the source of said first transistor is coupled to a first voltage wire and the signal at the drain of said first transistor is said second output signal;
a second transistor having a source, a gate and a drain, wherein the gate of said second transistor is coupled to the drain of said first transistor, the drain of said second transistor is coupled to the gate of said first transistor, the source of said second transistor is coupled to said first voltage wire, and the signal at the drain of said second transistor is said first output signal;
a third transistor having a source, a gate and a drain, wherein the gate of said third transistor is coupled to the drain of said second transistor, the drain of said third transistor is coupled to the drain of said first transistor, and the source of said third transistor is coupled to a second voltage wire;
a fourth transistor having a source, a gate and a drain, wherein the gate of said fourth transistor is coupled to the drain of said first transistor, the drain of said fourth transistor is coupled to the gate of said third transistor, and the source of said fourth transistor is coupled to said second voltage wire;
a first converter having an input end and an output end, wherein the input end of said first converter receives said first input signal and the output end of said first converter is coupled to the drain of said first transistor;
a second converter having an input end and an output end, wherein the input end of said second converter receives said second input signal and the output end of said second converter is coupled to the drain of said second transistor;
a third converter having an input end and an output end, wherein the input end of said third converter receives said control voltage and the output end of said third converter is coupled to the drain of said first transistor; and
a fourth converter having an input end and an output end, wherein the input end of said fourth converter receives said control voltage and the output end of said fourth converter is coupled to the drain of said second transistor.

2. The high-speed low-noise voltage-controlled delay cell as recited in claim 1, wherein the length-width ratio of said first transistor is equal to that of said second transistor.

3. The high-speed low-noise voltage-controlled delay cell as recited in claim 1, wherein the length-width ratio of said first transistor is larger than or equal to that of said third transistor.

4. The high-speed low-noise voltage-controlled delay cell as recited in claim 1, wherein the length-width ratio of said third transistor is equal to that of said fourth transistor.

5. The high-speed low-noise voltage-controlled delay cell as recited in claim 1, wherein said first transistor and said second transistor are N-type MOSFETs (metal oxide semiconductor field effect transistors).

6. The high-speed low-noise voltage-controlled delay cell as recited in claim 1, wherein said third transistor and said fourth transistor are P-type MOSFETs (metal oxide semiconductor field effect transistors).

7. The high-speed low-noise voltage-controlled delay cell as recited in claim 1, wherein:
said first converter comprises a fifth transistor having a source, a gate and a drain, wherein the source of said fifth transistor is coupled to said first voltage wire, the gate of said fifth transistor is the input end of said first converter, and the drain of said fifth transistor is the output end of said first converter; and
said second converter comprises a sixth transistor having a source, a gate and a drain, wherein the source of said sixth transistor is coupled to said first voltage wire, the gate of said sixth transistor is the input end of said second converter, and the drain of said sixth transistor is the output end of said second converter.

8. The high-speed low-noise voltage-controlled delay cell as recited in claim 7, wherein said fifth transistor and said sixth transistor are N-type MOSFETs (metal oxide semiconductor field effect transistors).

9. The high-speed low-noise voltage-controlled delay cell as recited in claim 7, wherein the length-width ratio of said fifth transistor is equal to that of said sixth transistor.

10. The high-speed low-noise voltage-controlled delay cell as recited in claim 7, wherein the length-width ratio of said fifth transistor is larger than or equal to that of said first transistor.

11. The high-speed low-noise voltage-controlled delay cell as recited in claim 1, wherein:
said first converter comprises a ninth transistor having a source, a gate and a drain, wherein the source of said ninth transistor is coupled to said second voltage wire, the gate of said ninth transistor is the input end of said first converter, and the drain of said ninth transistor is the output end of said first converter; and
said second converter comprises a tenth transistor having a source, a gate and a drain, wherein the source of said tenth transistor is coupled to said second voltage wire, the gate of said tenth transistor is the input end of said second converter, and the drain of said tenth transistor is the output end of said second converter.

12. The high-speed low-noise voltage-controlled delay cell as recited in claim 11, wherein said ninth transistor and said tenth transistor are P-type MOSFETs (metal oxide semiconductor field effect transistors).

13. The high-speed low-noise voltage-controlled delay cell as recited in claim 1, wherein:
said third converter comprises a seventh transistor having a source, a gate and a drain, wherein the source of said seventh transistor is coupled to said second voltage wire, the gate of said seventh transistor is the input end of said third converter, and the drain of said seventh transistor is the output end of said third converter; and
said fourth converter comprises an eighth transistor having a source, a gate and a drain, wherein the source of said eighth transistor is coupled to said second voltage wire, the gate of said eighth transistor is the input end of said fourth converter, and the drain of said eighth transistor is the output end of said fourth converter.

14. The high-speed low-noise voltage-controlled delay cell as recited in claim 13, wherein said seventh transistor and said eighth transistor are P-type MOSFETs (metal oxide semiconductor field effect transistors).

15. The high-speed low-noise voltage-controlled delay cell as recited in claim 1, wherein:
said third converter comprises an eleventh transistor having a source, a gate and a drain, wherein the source of said eleventh transistor is coupled to said first voltage wire, the gate of said eleventh transistor is the input end of said third converter, and the drain of said eleventh transistor is the output end of said third converter; and
said fourth converter comprises a twelfth transistor having a source, a gate and a drain, wherein the source of said twelfth transistor is coupled to said first voltage wire, the gate of said twelfth transistor is the input end of said fourth converter, and the drain of said twelfth transistor is the output end of said fourth converter.

16. The high-speed low-noise voltage-controlled delay cell as recited in claim 15, wherein said eleventh transistor and said twelfth transistor are N-type MOSFETs (metal oxide semiconductor field effect transistors).

17. The high-speed low-noise voltage-controlled delay cell as recited in claim 1, wherein said first voltage wire is the grounding wire and said second voltage wire is the power supply voltage wire.

18. The high-speed low-noise voltage-controlled delay cell as recited in claim 1, which is suitable for a VCO (voltage-controlled oscillator).
